(19) United States
(12) Patent Application Publication
(10) Pub. No.: US 2016/0075971 A1
(43) Pub. Date: Mar. 17, 2016

(54) COPPER CLEANING AND PROTECTION FORMULATIONS

(71) Applicants: Jun LIU, Brookfield, CT (US); Laisheng SUN, Danbury, CT (US); Steven MEDD, Danbury, CT (US); Jeffrey A. BARNES, Bethlehem, CT (US); Peter WRSCHKA, Phoenix, AZ (US); Elizabeth THOMAS, Danbury, CT (US)

(72) Inventors: Jun LIU, Brookfield, CT (US); Laisheng SUN, Danbury, CT (US); Steven MEDD, Danbury, CT (US); Jeffrey A. BARNES, Bethlehem, CT (US); Peter WRSCHKA, Phoenix, AZ (US); Elizabeth THOMAS, Danbury, CT (US)

(73) Assignee: ADVANCED TECHNOLOGY MATERIALS, INC., Danbury, CT (US)

(21) Appl. No.: 14/785,972

(22) PCT Filed: Apr. 22, 2014
(86) PCT No.: PCT/US14/34872

§ 371 Date: Oct. 21, 2015

Related U.S. Application Data
(60) Provisional application No. 61/814,518, filed on Apr. 22, 2013.

(51) Int. Cl. C11D 3/00; C11D 11/00; H01L 21/02; C11D 3/30

(52) U.S. Cl. CPC C11D 3/0073; C11D 3/0042; C11D 3/30; C11D 11/0047; H01L 21/02068

(57) ABSTRACT

A cleaning composition and process for cleaning post-chemical mechanical polishing (CMP) residue and contaminants from a microelectronic device having said residue and contaminants thereon. The cleaning compositions include corrosion inhibitor(s) and surfactant(s). The composition achieves highly efficacious cleaning of the post-CMP residue and contaminant material from the surface of the microelectronic device without compromising the low-k dielectric material or the copper interconnect material.

### FIELD

The present invention relates generally to compositions including corrosion inhibitors and surfactants for cleaning residue and/or contaminants from microelectronic devices having same thereon, preferably from microelectronic devices comprising copper-containing material.

### DESCRIPTION OF THE RELATED ART

Microelectronic device wafers are used to form integrated circuits. The microelectronic device wafer includes a substrate, such as silicon, into which regions are patterned for deposition of different materials having insulative, conductive or semi-conductive properties.

In order to obtain the correct patterning, excess material used in forming the layers on the substrate must be removed. Further, to fabricate functional and reliable circuitry, it is important to prepare a flat or planar microelectronic wafer surface prior to subsequent processing. Thus, it is necessary to remove and/or polish certain surfaces of a microelectronic device wafer.

Chemical Mechanical Polishing or Planarization (“CMP”) is a process in which material is removed from a surface of a microelectronic device wafer, and the surface is polished (more specifically, planarized) by coupling a physical process such as abrasion with a chemical process such as oxidation or chelation. In its most rudimentary form, CMP involves applying slurry, e.g., a solution of an abrasive and an active chemistry, to a polishing pad that buffs the surface of a microelectronic device wafer to achieve the removal, planarization, and polishing processes. It is not desirable for the removal or polishing process to be comprised of purely physical or purely chemical action, but rather the synergistic combination of both in order to achieve fast, uniform removal. In the fabrication of integrated circuits, the CMP slurry should also be able to preferentially remove films that comprise complex layers of metals and other materials so that highly planar surfaces can be produced for subsequent photolithography, or patterning, etching and thin-film processing.

Recently, copper has been increasingly used for metal interconnects in integrated circuits. In copper damascene processes commonly used for metallization of circuitry in microelectronic device fabrication, the layers that must be removed and planarized include copper layers having a thickness of about 1-1.5 μm and copper seed layers having a thickness of about 0.05-0.15 min. These copper layers are separated from the dielectric material surface by a layer of barrier material, typically about 50-300 Å thick, which prevents diffusion of copper into the oxide dielectric material. One key to obtaining good uniformity across the wafer surface after polishing is to use a CMP slurry that has the correct removal selectivities for each material.

The foregoing processing operations, involving wafer substrate surface preparation, deposition, plating, etching and chemical mechanical polishing, variously require cleaning operations to ensure that the microelectronic device product is free of contaminants that would otherwise deleteriously affect the function of the product, or even render it useless for its intended function. Often, particles of these contaminants are smaller than 0.3 μm.

One particular issue in this respect is the residues that are left on the microelectronic device substrate following CMP processing. Such residues include CMP material and corrosion inhibitor compounds such as benzotriazole (BTA). If not removed, these residues can cause damage to copper lines or severely roughen the copper metallization, as well as cause poor adhesion of post-CMP applied layers on the device substrate. Severe roughening of copper metallization is particularly problematic, since overly rough copper can cause poor electrical performance of the product microelectronic device.

Another residue-producing process common to microelectronic device manufacturing involves gas-phase plasma etching to transfer the patterns of developed photoresist coatings to the underlying layers, which may consist of hardmask, interlevel dielectric (ILD), and etch stop layers. Post-gas phase plasma etch residues, which may include chemical elements present on the substrate and in the plasma gases, are typically deposited on the back end of the line (BEOL) structures and if not removed, may interfere with subsequent silicidation or contact formation. Conventional cleaning chemistries often damage the ILD, absorb into the pores of the ILD thereby increasing the dielectric constant, and/or corrode the metal structures.

Disadvantageously, even though many prior art residue removal formulations display good performance characteristics, the amount of copper loss still remains high. Accordingly, it is an object of the present invention to introduce an improved residue removal formulation which reduces copper loss while concomitantly enhancing cleaning efficiency. Moreover, it is desirable to prevent the re-deposition of slurry particles which will further enhance the cleaning performance.

### SUMMARY

The present invention generally relates to a composition and process for cleaning residue and/or contaminants from microelectronic devices having said residue and contaminants thereon. The cleaning compositions of the invention include at least one corrosion inhibitor and at least one surfactant. The residue may include post-CMP, post-etch, and/or post-ash residue. Preferably, the microelectronic device comprises exposed copper-containing material.

In one aspect, a cleaning composition is described, said cleaning composition comprising at least one solvent, at least one corrosion inhibitor, at least one amine, at least one quaternary base, and at least one surfactant, wherein the corrosion inhibitor comprises a species selected from the group consisting of: adenosine; adenine; methylated adenine; dimethylated adenine; adenosine derivatives selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof; adenosine degradation products; and combinations thereof.

In another aspect, a method of removing residue and contaminants from a microelectronic device having said residue and contaminants thereon is described, said method comprising contacting the microelectronic device with a cleaning composition for sufficient time to at least partially clean said residue and contaminants from the microelectronic device, wherein the cleaning composition includes at least one solvent, at least one corrosion inhibitor, at least one amine, at least one quaternary base, and at least one surfactant, wherein the corrosion inhibitor comprises a species selected from the group consisting of: adenosine; adenine; methylated adenine; dimethylated adenine; adenosine derivatives selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof; adenosine degradation products; and combinations thereof.

Other aspects, features and advantages will be more fully apparent from the ensuing disclosure and appended claims.

### BRIEF DESCRIPTION OF THE DRAWINGS

FIG. 1 illustrates the copper etch rates of cleaning compositions comprising surfactants.

### DETAILED DESCRIPTION, AND PREFERRED EMBODIMENTS THEREOF

The present invention relates generally to compositions useful for the removal of residue and contaminants from a microelectronic device having such material(s) thereon. The compositions are particularly useful for the removal of post-CMP, post-etch or post-ash residue.

Many prior art residue removal formulations display good performance characteristics, however, the amount of copper loss still remains high. The approach to lowering copper corrosion while enhancing residue removal includes: increasing the concentration of copper corrosion inhibitor, decreasing the concentration of reducing agent, or a combination of both. In another embodiment, surfactant is added to the cleaning composition to minimize copper loss as well as substantially prevent the re-deposition of slurry particles onto the microelectronic device. Any combination of copper corrosion inhibitor increase, reducing agent decrease, and surfactant addition is contemplated herein.

For ease of reference, “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

As used herein, “residue” corresponds to particles generated during the manufacture of a microelectronic device including, but not limited to, plasma etching, ashing, chemical mechanical polishing, wet etching, and combinations thereof.

As used herein, “contaminants” correspond to chemicals present in the CMP slurry, reaction by-products of the polishing slurry, chemicals present in the wet etching composition, reaction by products of the wet etching composition, and any other materials that are the by-products of the CMP process, the wet etching, the plasma etching or the plasma ashing process.

As used herein, “post-CMP residue” corresponds to particles from the polishing slurry, e.g., silica-containing particles, chemicals present in the slurry, reaction by-products of the polishing slurry, carbon-rich particles, polishing pad particles, brush deloading particles, equipment materials of construction particles, copper, copper oxides, organic residues, and any other materials that are the by-products of the CMP process.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, “complexing agent” includes those compounds that are understood by one skilled in the art to be complexing agents, chelating agents and/or sequestering agents. Complexing agents will chemically combine with or physically hold the metal atom and/or metal ion to be removed using the compositions described herein.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, tungsten, and other refractory metals and their nitrides and silicides. Additional barrier layer materials contemplated include cobalt, molybdenum, rhenium, their nitrides and silicides, and alloys thereof, including, but not limited to, pure cobalt, CoWP, CoWB, cobalt nitrides (including cobalt nitrides comprising additional elements such as Ta or Li), CoW, CoP, CoSi, and cobalt silicide.

As defined herein, “post-etch residue” corresponds to material remaining following gas-phase plasma etching processes, e.g., BEOL dual damascene processing, or wet etching processes. The post-etch residue may be organic, organometallic, organosilicic, or inorganic in nature, for example, silicon-containing material, carbon-based organic material, and etch gas residue such as oxygen and fluorine.

As defined herein, “post-ash residue,” as used herein, corresponds to material remaining following oxidative or reductive plasma ashing to remove hardened photoresist and/or bottom anti-reflective coating (BARC) materials. The post-ash residue may be organic, organometallic, organosilicic, or inorganic in nature.

“Substantially devoid” is defined herein as less than 2 wt. %, preferably less than 1 wt. %, more preferably less than 0.5 wt. %, even more preferably less than 0.1 wt. %, and most preferably 0 wt. %.

As used herein, “about” is intended to correspond to ±5% of the stated value.

As defined herein, “reaction or degradation products” include, but are not limited to, product(s) or byproduct(s) formed as a result of catalysis at a surface, oxidation, reduction, reactions with the compositional components, or that otherwise polymerize; product(s) or byproduct(s) formed formed as a result of a change(s) or transformation(s) in which a substance or material (e.g., molecules, compounds, etc.) combines with other substances or materials, interchanges constituents with other substances or materials, decomposes, rearranges, or is otherwise chemically and/or physically altered, including intermediate product(s) or byproduct(s) of any of the foregoing or any combination of the foregoing reaction(s), change(s) and/or transformation(s). It should be appreciated that the reaction or degradation products may have a larger or smaller molar mass than the original reactant.

As used herein, “fluoride-containing sources” are those compounds including a fluoride anion (F⁻).

As used herein, “suitability” for cleaning residue and contaminants from a microelectronic device having said residue and contaminants thereon corresponds to at least partial removal of said residue/contaminants from the microelectronic device. Cleaning efficacy is rated by the reduction of objects on the microelectronic device. For example, pre- and post-cleaning analysis may be carried out using an atomic force microscope. The particles on the sample may be registered as a range of pixels. A histogram (e.g., a Sigma Scan Pro) may be applied to filter the pixels in a certain intensity, e.g., 231-235, and the number of particles counted. The particle reduction may be calculated using:

$$Cleaning Efficacy = \frac{( Number of PreClean Objects - Number of PostClean Objects )}{Number of PreClean Objects} \times 100$$

Notably, the method of determination of cleaning efficacy is provided for example only and is not intended to be limited to same. Alternatively, the cleaning efficacy may be considered as a percentage of the total surface that is covered by particulate matter. For example, AFM's may be programmed to perform a z-plane scan to identify topographic areas of interest above a certain height threshold and then calculate the area of the total surface covered by said areas of interest. One skilled in the art would readily understand that the less area covered by said areas of interest post-cleaning, the more efficacious the cleaning composition. Preferably, at least 75% of the residue/contaminants are removed from the microelectronic device using the compositions described herein, more preferably at least 90%, even more preferably at least 95%, and most preferably at least 99% of the residue/contaminants are removed.

Compositions described herein may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

The cleaning compositions include at least one corrosion inhibitor, where the corrosion inhibitor component is added to the cleaning composition to lower the corrosion rate of metals, e.g., copper, aluminum, as well as enhance the cleaning performance. Corrosion inhibitors contemplated include, but are not limited to: ribosylpurines such as N-ribosylpurine, adenosine, guanosine, 2-aminopurine riboside, 2-methoxyadenosine, and methylated or deoxy derivatives thereof, such as N-methyladenosine (C₁₁H₁₅N₅O₄), N,N-dimethyladenosine (C₁₂H₁₇N₅O₄), trimethylated adenosine (C₁₃H₁₉N₅O₄), trimethyl N-methyladenosine (C₁₄H₂₁N₅O₄), C-4′-methyladenosine, and 3-deoxyadenosine; degradation products of adenosine and adenosine derivatives including, but not limited to, adenine (C₅H₅N₅), methylated adenine (e.g., N-methyl-7H-purin-6-amine, C₆H₇N₅), dimethylated adenine (e.g., N,N-dimethyl-7H-purin-6-amine, C₇H₉N₅), N4,N4-dimethylpyrimidine-4,5,6-triamine (C₆H₁₁N₅), 4,5,6-triaminopyrimidine, allantoin (C₄H₆N₄O₃), hydroxylated C—O—O—C dimers ((C₅H₄N₅O₂)₂), C—C bridged dimers ((C₅H₄N₅)₂ or (C₅H₄N₅O)₂), ribose (C₅H₁₀O₅), methylated ribose (e.g., 5-(methoxymethyl)tetrahydrofuran-2,3,4-triol, C₆H₁₂O₅), tetramethylated ribose (e.g., 2,3,4-trimethoxy-5-(methoxymethyl)tetrahydrofuran, C₉H₁₈O₅), and other ribose derivatives such as methylated hydrolyzed diribose compounds; purine-saccharide complexes including, but not limited to, xylose, glucose, etc.; other purine compounds such as purine, guanine, hypoxanthine, xanthine, theobromine, caffeine, uric acid, and isoguanine, and methylated or deoxy derivatives thereof; triaminopyrimidine and other substituted pyrimidines such as amino-substituted pyrimidines; dimers, trimers or polymers of any of the compounds, reaction or degradation products, or derivatives thereof; and combinations thereof. For example, the corrosion inhibitors may comprise at least one species selected from the group consisting of N-ribosylpurine, 2-aminopurine riboside, 2-methoxyadenosine, N-methyladenosine, N,N-dimethyladenosine, trimethylated adenosine, trimethyl N-methyladenosine, C-4′-methyladenosine, 3-deoxyadenosine; methylated adenine, dimethylated adenine, N4,N4-dimethylpyrimidine-4,5,6-triamine, 4,5,6-triaminopyrimidine, hydroxylated C—O—O—C dimers, C—C bridged dimers, ribose, methylated ribose, tetramethylated ribose, xylose, glucose, isoguanine, triaminopyrimidine, amino-substituted pyrimidines, and combinations thereof. Alternatively, the corrosion inhibitors may include at least one species selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof. In another alternative, the corrosion inhibitor comprises adenosine. In yet another alternative, the corrosion inhibitor comprises adenine. In still another alternative, the corrosion inhibitor include adenosine degradation products and derivatives thereof. As disclosed, combinations of the corrosion inhibitors are also contemplated, for example, adenine in combination with a purine.

In one embodiment, a cleaning composition is described, wherein said cleaning composition comprises at least one solvent, at least one corrosion inhibitor, and at least one of at least one surfactant and at least one reducing agent. Preferably, the solvent comprises water, and more preferably deionized water.

In a further embodiment the cleaning composition comprises, consists of, or consists essentially of at least one corrosion inhibitor, at least one quaternary base, at least one organic amine, at least one solvent (e.g., water), at least one surfactant, and optionally at least one additional species selected from the group consisting of at least one reducing agent, at least one complexing agent, at least one supplemental corrosion inhibitor, at least one alcohol, and NR¹R²R³R⁴OH, where R¹, R², R³ and R⁴ can be the same as or different from one another and are selected from the group consisting of H, a methyl and an ethyl group, with the proviso that at least one of R¹, R², R³ and R⁴ must be H. In another embodiment, the cleaning composition comprises, consists of, or consists essentially of at least one corrosion inhibitor, at least one quaternary base, at least one organic amine, at least one solvent (e.g., water), at least one reducing agent, and optionally at least one additional species selected from the group consisting of at least one complexing agent, at least one supplemental corrosion inhibitor, at least one alcohol, and NR¹R²R³R⁴OH, where R¹, R², R³ and R⁴ can be the same as or different from one another and are selected from the group consisting of H, a methyl and an ethyl group, with the proviso that at least one of R¹, R², R³ and R⁴ must be H.

In a particularly preferred embodiment, the cleaning composition comprises, consists of or consists essentially of at least one quaternary base, at least one organic amine, at least one corrosion inhibitor, at least one surfactant, and at least one solvent (e.g., water), wherein the corrosion inhibitor is selected from the group consisting of adenosine, adenosine degradation products, and derivatives thereof. The cleaning composition may optionally further comprise at least one reducing agent, at least one complexing agent, at least one supplemental corrosion inhibitor, at least one alcohol, and NR¹R²R³R⁴OH (as defined above), residue material, or combinations thereof. In another particularly preferred embodiment, the cleaning composition comprises, consists of or consists essentially of at least one quaternary base, at least one organic amine, at least one corrosion inhibitor, at least one reducing agent, and at least one solvent (e.g., water), wherein the corrosion inhibitor is selected from the group consisting of adenosine, adenosine degradation products, and derivatives thereof and wherein the at least one reducing agent comprises ascorbic acid and gallic acid.

In a further preferred embodiment, a composition comprising, consisting of, or consisting essentially of at least one quaternary base, at least one organic amine, at least one corrosion inhibitor, at least one solvent, and at least one of at least one surfactant and at least one reducing agent is described, wherein the corrosion inhibitor includes at least one of:
(1) at least one compound selected from the group consisting of ribosylpurine compounds, methylated or deoxy derivatives of purine, purine-saccharide complexes, derivatives thereof, and combinations thereof;
(2) at least one reaction or degradation product mixture resulting from the breakdown/degradation of at least one compound in (1) after contacting said compound with an aqueous solution containing the at least one quaternary base and the at least one amine;
(3) at least one compound selected from the group consisting of N-ribosylpurine, 2-aminopurine riboside, 2-methoxyadenosine, N-methyladenosine, N,N-dimethyladenosine, trimethylated adenosine, trimethyl N-methyladenosine, C-4′-methyladenosine, 3-deoxyadenosine; methylated adenine, dimethylated adenine, N4,N4-dimethylpyrimidine-4,5,6-triamine, 4,5,6-triaminopyrimidine, hydroxylated C—O—O—C dimers, C—C bridged dimers, ribose, methylated ribose, tetramethylated ribose, xylose, glucose, isoguanine, triaminopyrimidine, amino-substituted pyrimidines, and combinations thereof;
(4) at least one compound selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof;
(5) adenosine;
(6) adenine;
(7) at least one compound selected from the group consisting of ribosylpurine compounds and methylated or deoxy derivatives thereof, purine-saccharide complexes, derivatives thereof, and combinations thereof; and/or
(8) degradation products of adenosine and adenosine derivatives.
   The cleaning compositions may optionally further comprise at least one complexing agent, at least one supplemental corrosion inhibitor, at least one alcohol, and NR¹R²R³R⁴OH (as defined above), residue material, or combinations thereof.

The cleaning composition is particularly useful for cleaning residue and contaminants, e.g., post-CMP residue, post-etch residue, post-ash residue, and contaminants from a microelectronic device structure. Regardless of the embodiment, the cleaning compositions are preferably substantially devoid of at least one of oxidizing agents; fluoride-containing sources; chemical mechanical abrasive materials; an alcohol having an ether-bond in the molecule; alkylpyrrolidones; surface interaction enhancing agents including, but not limited to, poly(acrylamide-co-diallyldiemethylammonium chloride), poly(acrylamide), poly(acrylic acid), poly(diallyldiemethylammonium chloride), diallyldimethylammonium chloride, acrylamide, acetoguanamine, and combinations thereof; alkali and/or alkaline earth metal bases; sugar alcohols; corrosion inhibiting metal halides; and combinations thereof, prior to removal of residue material from the microelectronic device. In addition, the cleaning compositions should not solidify to form a polymeric solid, for example, photoresist.

Illustrative amines that may be useful in specific compositions include species having the general formula NR¹R²R³, wherein R¹, R² and R³ may be the same as or different from one another and are selected from the group consisting of hydrogen, straight-chained or branched C₁-C₆ alkyl (e.g., methyl, ethyl, propyl, butyl, pentyl, and hexyl), straight-chained or branched C₁-C₆ alcohol (e.g., methanol, ethanol, propanol, butanol, pentanol, and hexanol), and straight chained or branched ethers having the formula R⁴—O—R⁵, where R⁴ and R⁵ may be the same as or different from one another and are selected from the group consisting of C₁-C₆ alkyls as defined above. Most preferably, at least one of R¹, R² and R³ is a straight-chained or branched C₁-C₆ alcohol. Examples include, without limitation, alkanolamines such as aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino-1-butanol, isobutanolamine, triethylenediamine, other C₁-C₈ alkanolamines and combinations thereof. When the amine includes the ether component, the amine may be considered an alkoxyamine, e.g., 1-methoxy-2-aminoethane. Alternatively, or in addition to the NR¹R²R³ amine, the amine may be a multi-functional amine including, but not limited to, tetraethylenepentamine (TEPA), pentamethyldiethylenetriamine (PMDETA), 4-(2-hydroxyethyl)morpholine (HEM), N-aminoethylpiperazine (N-AEP), ethylenediaminetetraacetic acid (EDTA), 1,2-cyclohexanediamine-N,N,N′,N′-tetraacetic acid (CDTA), glycine/ascorbic acid, iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, glycine, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, and combinations thereof. Preferably, the amines include at least one species selected from the group consisting of monoethanolamine, triethanolamine, EDTA, CDTA, HIDA, and N-AEP. Most preferably, the amine comprises monoethanolamine.

Quaternary bases contemplated herein include compounds having the formula NR¹R²R³R⁴OH, wherein R¹, R², R³ and R⁴ may be the same as or different from one another and are selected from the group consisting of hydrogen, straight-chained or branched C₁-C₆ alkyl (e.g., methyl, ethyl, propyl, butyl, pentyl, and hexyl), and substituted or unsubstituted C₆-C₁₀ aryl, e.g., benzyl. Tetraalkylammonium hydroxides that are commercially available include tetraethylammonium hydroxide (TEAH), tetramethyammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), and combinations thereof, may be used. Tetraalkylammonium hydroxides which are not commercially available may be prepared in a manner analogous to the published synthetic methods used to prepare TMAH, TEAH, TPAH, TBAH, TBMAH, and BTMAH, which are known to one ordinary of skill in the art. Other widely used quaternary ammonium bases include choline hydroxide and tris(2-hydroxyethyl) methylammonium hydroxide. Although not a quaternary base, it is contemplated that the bases cesium hydroxide or rubidium hydroxide may be used in the absence of or the presence of the above-identified quaternary bases. Preferably, the quaternary base comprises TMAH.

Although not wishing to be bound by theory, it is thought that the role of surfactants in the cleaning compositions described herein (when present) is to modify the surface properties of copper by wetting, to reduce the attractive forces of particles on the microelectronic device surface, and to reduce the level of particulate contamination on the microelectronic device surface. Surfactants for use in the compositions described herein include, but are not limited to, amphoteric salts, cationic surfactants, anionic surfactants, zwitterionic surfactants, non-ionic surfactants, and combinations thereof including, but not limited to, bis(2-ethylhexyl)phosphate, perfluoroheptanoic acid, prefluorodecanoic acid, trifluoromethanesulfonic acid, phosphonoacetic acid, dodecenylsuccinic acid, dioctadecyl hydrogen phosphate, octadecyl dihydrogen phosphate, dodecylamine, dodecenylsuccinic acid monodiethanol amide, lauric acid, palmitic acid, oleic acid, juniperic acid, 12 hydroxystearic acid, dodecyl phosphate. Non-ionic surfactants contemplated include, but are not limited to, polyoxyethylene lauryl ether (Emalmin NL-100 (Sanyo), Brij 30, Brij 98, Brij 35), dodecenylsuccinic acid monodiethanol amide (DSDA, Sanyo), ethylenediamine tetrakis(ethoxylate-block-propoxylate) tetrol (Tetronic 90R4), polyethylene glycols (e.g., PEG 400), polypropylene glycols, polyethylene or polypropylene glycol ethers, block copolymers based on ethylene oxide and propylene oxide (Newpole PE-68 (Sanyo), Pluronic L31, Pluronic 31R1, Pluronic L61, Pluronic F-127), polyoxypropylene sucrose ether (SN008S, Sanyo), t-octylphenoxypolyethoxyethanol (Triton X100), 10-ethoxy-9,9-dimethyldecan-1-amine (TRITON® CF-32), Polyoxyethylene (9) nonylphenylether, branched (IGEPAL CO-250), polyoxyethylene (40) nonylphenylether, branched (IGEPAL CO-890), polyoxyethylene sorbitol hexaoleate, polyoxyethylene sorbitol tetraoleate, polyethylene glycol sorbitan monooleate (Tween 80), sorbitan monooleate (Span 80), a combination of Tween 80 and Span 80, alcohol alkoxylates (e.g., Plurafac RA-20), alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives such as SIS6952.0 (Siliclad, Gelest), siloxane modified polysilazane such as PP1-SG10 Siliclad Glide 10 (Gelest), silicone-polyether copolymers such as Silwet L-77 (Setre Chemical Company), Silwet ECO Spreader (Momentive), and ethoxylated fluorosurfactants (ZONYL® FSO-100, ZONYL® FSN-100). Cationic surfactants contemplated include, but are not limited to, cetyl trimethylammonium bromide (CTAB), heptadecanefluorooctane sulfonic acid, tetraethylammonium, stearyl trimethylammonium chloride (Econol TMS-28, Sanyo), 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, Aliquat® 336 and oxyphenonium bromide, guanidine hydrochloride (C(NH₂)₃Cl) or triflate salts such as tetrabutylammonium trifluoromethanesulfonate, dimethyldioctadecylammonium chloride, dimethyldihexadecylammonium bromide and di(hydrogenated tallow)dimethylammonium chloride (e.g., Arquad 2HT-75, Akzo Nobel). Anionic surfactants contemplated include, but are not limited to, ammonium polyacrylate (e.g., DARVAN 821A), modified polyacrylic acid in water (e.g., SOKALAN CP10S), phosphate polyether ester (e.g., TRITON H-55), decylphosphonic acid, dodecylphosphonic acid (DDPA), tetradecylphosphonic acid, hexadecylphosphonic acid, octadecylphosphonic acid, dodecylbenzenesulfonic acid, poly(acrylic acid sodium salt), sodium polyoxyethylene lauryl ether, sodium dihexylsulfosuccinate, dicyclohexyl sulfosuccinate sodium salt, sodium 7-ethyl-2-methyl-4-undecyl sulfate (Tergitol 4), SODOSIL RM02, and phosphate fluorosurfactants such as Zonyl FSJ and ZONYL® UR. Zwitterionic surfactants include, but are not limited to, acetylenic diols or modified acetylenic diols (e.g., SURFONYL® 504), cocamido propyl betaine, ethylene oxide alkylamines (AOA-8, Sanyo), N,N-dimethyldodecylamine N-oxide, sodium cocaminpropinate (LebonApl-D, Sanyo), 3-(N,N-dimethylmyristylammonio)propanesulfonate, and (3-(4-heptyl)phenyl-3-hydroxypropyl)dimethylammoniopropanesulfonate. Preferably, the at least one surfactant comprises dodecylbenzene sulfonic acid, dodecyl phosphonic acid, dodecyl phosphate, TRITON X-100, SOKALAN CP10S, PEG 400, and PLURONIC F-127. When present, the amount of surfactant may be in a range from about 0.001 wt % to about 1 wt %, preferably about 0.1 wt % to about 1 wt %, based on the total weight of the concentrate.

When surfactants are present in the cleaning compositions described herein, defoaming agents can be added. Defoaming agents are substances that induce rapid foam collapse or suppress the foaming level in a solution. Preferably, defoaming agents have to fulfill three conditions: they should be insoluble in the solution, they should have a positive spreading coefficient, and they should have a positive entering coefficient. Defoamers contemplated generally include, but are not limited to, silicone-oil based, mineral-oil based, natural-oil based, acetylenic-based, and phosphoric acid ester-based defoaming agents. More preferably, the defoaming agents include, but are not limited to, ethylene oxide/propylene oxide block copolymers such as Pluronic® (BASF®) products (e.g., Pluronic® 17R2, Pluronic® 17R4, Pluronic® 31R1 and Pluronic® 25R2), alcohol alkoxylates such as Plurafac® products (BASF®) (e.g., Plurafac® PA20), fatty alcohol alkoxylates such as Surfonic® (Huntsmen) (e.g., Surfonic®P1), phosphoric acid ester blends with non-ionic emulsifiers such as Defoamer M (Ortho Chemicals Australia Pty. Ltd.), and Super Defoamer 225 (Varn Products), and combinations thereof. Notably, Defoamer M also acts as a wetting agent and as such, when used, Defoamer M may be both the surfactant and the defoaming agent. In addition, diethylene glycol monobutyl ether, propylene glycol methyl ether, dipropylene glycol methyl ether (DPGME), tripropylene glycol methyl ether, dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, and propylene glycol may be used alone or in combination with the other defoaming agents for effective defoaming. In one embodiment, the defoaming agent is selected from the group consisting of ethylene oxide/propylene oxide block copolymers, alcohol alkoxylates, fatty alcohol alkoxylates, phosphoric acid ester blends with non-ionic emulsifiers, and combinations thereof. In another embodiment, the defoaming agent is selected from the group consisting of ethylene oxide/propylene oxide block copolymers, alcohol alkoxylates, fatty alcohol alkoxylates, and combinations thereof. In still another embodiment, the defoaming agent is an ethylene oxide/propylene oxide block copolymer.

When reducing agents are included, the reducing agent(s) contemplated herein include species selected from the group consisting of ascorbic acid, L(+)-ascorbic acid, isoascorbic acid, ascorbic acid derivatives, gallic acid, glyoxal, and combinations thereof. In a particularly preferred embodiment, the cleaning composition includes ascorbic acid. In another particularly preferred embodiment, the cleaning composition includes ascorbic acid and gallic acid. When present, the weight percent ratios of reducing agent to corrosion inhibitor is about 1:1 to about 200:1, preferably about 20:1 to about 150:1, even more preferably about 25:1 to about 40:1 or about 110:1 to about 150:1.

The cleaning compositions may further include supplemental corrosion inhibitors, in addition to the corrosion inhibitors enumerated above, including, but not limited to, ascorbic acid, L(+)-ascorbic acid, isoascorbic acid, ascorbic acid derivatives, benzotriazole, citric acid, ethylenediamine, gallic acid, oxalic acid, tannic acid, 1,2,4-triazole (TAZ), tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1,2,3-triazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, benzoic acid, ammonium benzoate, catechol, pyrogallol, resorcinol, hydroquinone, cyanuric acid, barbituric acid and derivatives such as 1,2-dimethylbarbituric acid, alpha-keto acids such as pyruvic acid, phosphonic acid and derivatives thereof such as 1-hydroxyethylidene-1,1-diphosphonic acid (HEDP), propanethiol, benzohydroxamic acids, heterocyclic nitrogen inhibitors, potassium ethylxanthate, and combinations thereof. For example, the cleaning compositions may include the combination of phenanthroline and ascorbic acid or glycine and ascorbic acid. In another preferred embodiment, the cleaning compositions include 1,2,4-triazole.

When alcohols are included, illustrative alcohols include, but are not limited to, straight-chained or branched C₁-C₆ alcohols (e.g., methanol, ethanol, propanol, butanol, pentanol, and hexanol), diols and triols. Preferably, the alcohol comprises isopropanol (IPA).

The optional complexing agents contemplated herein include, but are not limited to, acetic acid, acetone oxime, acrylic acid, adipic acid, alanine, arginine, asparagine, aspartic acid, betaine, dimethyl glyoxime, formic acid, fumaric acid, gluconic acid, glutamic acid, glutamine, glutaric acid, glyceric acid, glycerol, glycolic acid, glyoxylic acid, histidine, iminodiacetic acid, isophthalic acid, itaconic acid, lactic acid, leucine, lysine, maleic acid, maleic anhydride, malic acid, malonic acid, mandelic acid, 2,4-pentanedione, phenylacetic acid, phenylalanine, phthalic acid, proline, propionic acid, pyrocatecol, pyromellitic acid, quinic acid, serine, sorbitol, succinic acid, tartaric acid, terephthalic acid, trimellitic acid, trimesic acid, tyrosine, valine, xylitol, salts and derivatives thereof, and combinations thereof. In a preferred embodiment, preferably the complexing agent comprises histidine.

The pH of the cleaning compositions described herein is greater than 7, preferably in a range from about 10 to greater than 14, more preferably in a range from about 12 to about 14. In a preferred embodiment, the pH of the cleaning composition is greater than 13.

In a particularly preferred embodiment, the cleaning composition comprises, consists of, or consists essentially of tetramethylammonium hydroxide, at least one amine, at least one corrosion inhibitor, at least one surfactant, and water. In yet another preferred embodiment, the cleaning composition comprises, consists of, or consists essentially of at least one solvent (e.g., water), at least one corrosion inhibitor, at least one amine, at least one quaternary base, and at least one surfactant, wherein the corrosion inhibitor comprises a species selected from the group consisting of: adenosine; adenine; methylated adenine; dimethylated adenine; adenosine derivatives selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof; adenosine degradation products; and combinations thereof. In another particularly preferred embodiment, the cleaning composition comprises, consists of, or consists essentially of tetramethylammonium hydroxide, at least one amine, at least one corrosion inhibitor, at least one reducing agent, and water. In yet another particularly preferred embodiment, the cleaning composition comprises, consists of, or consists essentially of tetramethylammonium hydroxide, at least one amine, at least one corrosion inhibitor, at least one surfactant, at least one reducing agent, and water. In another example, the cleaning composition can comprise, consist of or consist essentially of TMAH, N-AEP, adenosine, at least one reducing agent, and water, wherein the at least one reducing agent comprises ascorbic acid, gallic acid, or a combination of ascorbic and gallic acids. In still another preferred embodiment, the cleaning composition comprises, consists of, or consists essentially of tetramethylammonium hydroxide, monoethanolamine, at least one corrosion inhibitor, at least one complexing agent, at least one supplemental corrosion inhibitor, and water.

With regards to compositional amounts, the weight percent ratios of each component is preferably as follows: about 0.1:1 to about 500:1 quaternary base to corrosion inhibitor, preferably about 5:1 to about 60:1, even more preferably about 10:1 to about 15:1 or about 45:1 to about 55:1; and about 0.1:1 to about 500:1 organic amine to corrosion inhibitor, preferably about 5:1 to about 60:1, even more preferably about 5:1 to about 15:1 or about 40:1 to about 50:1. It is possible that the corrosion inhibitor will undergo degradation in the presence of the quaternary base and as such, the weight percent ratios correspond to the concentrate at the time of combination of the quaternary base and the corrosion inhibitor. It will be understood by one skilled in the art that in the event the corrosion inhibitor does undergo degradation, the weight percent may change over time and is monitorable using techniques and mathematical principles known in the art. The concentration of the corrosion inhibitor in the concentrate at the time of combination of the quaternary base and the corrosion inhibitor is in the range of from about 0.001 wt % to about 2 wt %, preferably about 0.001 wt % to about 0.5 wt % and most preferably about 0.1 wt % to about 1.1 wt %.

The range of weight percent ratios of the components will cover all possible concentrated or diluted embodiments of the composition. Towards that end, in one embodiment, a concentrated cleaning composition is provided that can be diluted for use as a cleaning solution. A concentrated composition, or “concentrate,” advantageously permits a user, e.g. CMP process engineer, to dilute the concentrate to the desired strength and pH at the point of use. Dilution of the concentrated cleaning composition may be in a range from about 1:1.5 to about 2500:1 diluent to concentrate, preferably about 5:1 to about 200:1, and most preferably about 20:1 to about 75:1, wherein the cleaning composition is diluted at or just before the tool with solvent, e.g., deionized water. It is to be appreciated by one skilled in the art that following dilution, the range of weight percent ratios of the components disclosed herein should remain unchanged. In another embodiment, the concentrate is used as is, i.e., without dilution.

The compositions described herein may have utility in applications including, but not limited to, post-etch residue removal, post-ash residue removal surface preparation, post-plating cleaning, copper seed etch/cleans, through-silicon via (TSV) cleans, microelectromechanical systems (MEMS) cleans, the cleaning of cobalt and cobalt alloy surfaces, and post-CMP residue removal. In addition, it is contemplated that the cleaning compositions described herein may be useful for the cleaning and protection of other metal (e.g., copper-containing) products including, but not limited to, decorative metals, metal wire bonding, printed circuit boards and other electronic packaging using metal or metal alloys.

In yet another preferred embodiment, the cleaning compositions described herein further include residue and/or contaminants. The residue and contaminants may be dissolved and/or suspended in the compositions. Preferably, the residue includes post-CMP residue, post-etch residue, post-ash residue, contaminants, or combinations thereof.

The cleaning compositions are easily formulated by simple addition of the respective ingredients and mixing to homogeneous condition. Furthermore, the compositions may be readily formulated as single-package formulations or multi-part formulations that are mixed at or before the point of use, e.g., the individual parts of the multi-part formulation may be mixed at the tool or in a storage tank upstream of the tool. The concentrations of the respective ingredients may be widely varied in specific multiples of the composition, i.e., more dilute or more concentrated, and it will be appreciated that the compositions described herein can variously and alternatively comprise, consist or consist essentially of any combination of ingredients consistent with the disclosure herein.

Accordingly, another aspect relates to a kit including, in one or more containers, one or more components adapted to form the compositions described herein. The kit may include, in one or more containers, at least one corrosion inhibitor, at least one quaternary base, at least one organic amine, at least one surfactant, and optionally at least one additional species selected from the group consisting of at least one reducing agent, at least one complexing agent, at least one supplemental corrosion inhibitor, and at least one alcohol, for combining with additional solvent, e.g., water and/or NR¹R²R³R⁴OH (as defined above), at the fab or the point of use. Alternatively, the kit may include, in a first container at least one corrosion inhibitor, and in a second container at least one quaternary base, at least one organic amine, at least one surfactant, and optionally at least one additional species selected from the group consisting of at least one reducing agent, at least one complexing agent, at least one supplemental corrosion inhibitor, and at least one alcohol, for combining with each other and additional solvent, e.g., water and/or NR¹R²R³R⁴OH (as defined above), at the fab or the point of use. In still another alternative, the kit may include, in one or more containers, at least one corrosion inhibitor, at least one quaternary base, at least one organic amine, at least one reducing agent, and optionally at least one additional species selected from the group consisting of at least one complexing agent, at least one supplemental corrosion inhibitor, and at least one alcohol, for combining with additional solvent, e.g., water and/or NR¹R²R³R⁴OH (as defined above), at the fab or the point of use. The containers of the kit must be suitable for storing and shipping said compositions, for example, NOWPak® containers (Advanced Technology Materials, Inc., Danbury, Conn., USA).

The one or more containers which contain the components of the composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended composition to a process tool.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” U.S. Patent Application No. 60/916,966 entitled “SYSTEMS AND METHODS FOR MATERIAL BLENDING AND DISTRIBUTION” filed on May 9, 2007 in the name of John E. Q. Hughes, and PCT/US08/63276 entitled “SYSTEMS AND METHODS FOR MATERIAL BLENDING AND DISTRIBUTION” filed on May 9, 2008 in the name of Advanced Technology Materials, Inc.

As applied to microelectronic manufacturing operations, the cleaning compositions described herein are usefully employed to clean post-CMP residue and/or contaminants from the surface of the microelectronic device. The cleaning compositions do not damage low-k dielectric materials or corrode metal interconnects on the device surface. Preferably the cleaning compositions remove at least 85% of the residue present on the device prior to residue removal, more preferably at least 90%, even more preferably at least 95%, and most preferably at least 99%. At the same time, the amount of copper corrosion is reduced.

In post-CMP residue and contaminant cleaning application, the cleaning composition may be used with a large variety of conventional cleaning tools such as megasonics and brush scrubbing, including, but not limited to, Verteq single wafer megasonic Goldfinger, OnTrak systems DDS (double-sided scrubbers), SEZ or other single wafer spray rinse, Applied Materials Mirra-Mesa™/Reflexion™/Reflexion LK™, and Megasonic batch wet bench systems.

In use of the compositions described herein for cleaning post-CMP residue, post-etch residue, post-ash residue and/or contaminants from microelectronic devices having same thereon, the cleaning composition typically is contacted with the device for a time of from about 5 sec to about 10 minutes, preferably about 1 sec to 20 min, preferably about 15 sec to about 5 min at temperature in a range of from about 20° C. to about 90° C., preferably about 20° C. to about 50° C. Such contacting times and temperatures are illustrative, and any other suitable time and temperature conditions may be employed that are efficacious to at least partially clean the post-CMP residue/contaminants from the device, within the broad practice of the method. “At least partially clean” and “substantial removal” both correspond to at removal of at least 85% of the residue present on the device prior to residue removal, more preferably at least 90%, even more preferably at least 95%, and most preferred at least 99%

Following the achievement of the desired cleaning action, the cleaning composition may be readily removed from the device to which it has previously been applied, as may be desired and efficacious in a given end use application of the compositions described herein. Preferably, the rinse solution includes deionized water. Thereafter, the device may be dried using nitrogen or a spin-dry cycle.

Yet another aspect relates to the improved microelectronic devices made according to the methods described herein and to products containing such microelectronic devices.

Another aspect relates to a recycled cleaning composition, wherein the cleaning composition may be recycled until residue and/or contaminant loading reaches the maximum amount the cleaning composition may accommodate, as readily determined by one skilled in the art.

A still further aspect relates to methods of manufacturing an article comprising a microelectronic device, said method comprising contacting the microelectronic device with a cleaning composition for sufficient time to clean post-CMP residue and contaminants from the microelectronic device having said residue and contaminants thereon, and incorporating said microelectronic device into said article, using a cleaning composition described herein.

In another aspect, a method of removing post-CMP residue and contaminants from a microelectronic device having same thereon is described, said method comprising:
polishing the microelectronic device with a CMP slurry;
contacting the microelectronic device with a cleaning composition described herein, for a sufficient time to remove post-CMP residue and contaminants from the microelectronic device to form a post-CMP residue-containing composition; and
continuously contacting the microelectronic device with the post-CMP residue-containing composition for a sufficient amount of time to effect substantial cleaning of the microelectronic device.

Another aspect relates to an article of manufacture comprising a cleaning composition, a microelectronic device wafer, and material selected from the group consisting of residue, contaminants and combinations thereof, wherein the cleaning composition comprises at least one solvent, at least one corrosion inhibitor, at least one organic amine, at least one surfactant, at least one quaternary base, and at least one solvent (e.g., water), wherein the residue comprises at least one of post-CMP residue, post-etch residue and post-ash residue. Alternatively, the cleaning composition comprises at least one solvent, at least one corrosion inhibitor, at least one organic amine, at least one reducing agent, at least one quaternary base, and at least one solvent (e.g., water).

The features and advantages are more fully shown by the illustrative examples discussed below.

### Example 1

A cleaning composition was prepared that comprised tetramethylammonium hydroxide, at least one amine, at least one corrosion inhibitor, at least one reducing agent, and water. The concentration of corrosion inhibitor in the control was 1×, and additional compositions were prepared whereby containing 2×, 3× and 4× corrosion inhibitor. Each cleaning composition was diluted 60:1 with deionized water. The anodic corrosion rate was measured at voltage biases ranging from 0 to 0.4V. The results are provided in Table 1.

TABLE 1
Anodic copper corrosion rate as a function
of corrosion inhibitor concentration.

| | Etch rate | Etch rate | Etch rate | Etch rate |
|---|---|---|---|---|
| Voltage Bias | (1X inhibi- | (2X inhibi- | (3X inhibi- | (4X inhibi- |
| (V vs. OCP) | tor)/Å/min | tor)/Å/min | tor)/Å/min | tor)/Å/min |
| 0 | 1.081 | 0.8366 | 0.7399 | 0.7246 |
| 0.1 | 7.612 | 5.837 | 5.520 | 5.250 |
| 0.2 | 24.07 | 17.43 | 16.03 | 14.59 |
| 0.3 | 40.10 | 29.34 | 26.95 | 24.18 |
| 0.4 | 58.23 | 41.66 | 37.28 | 33.32 |

It can be seen that increasing the amount of copper corrosion inhibitor in a cleaning composition reduced the copper corrosion rate at voltage biases from 0 to 0.4V.

Similarly, a cleaning composition was prepared that comprised tetramethylammonium hydroxide, at least one amine, at least one corrosion inhibitor, gallic acid, at least one additional reducing agent, and water. The concentration of gallic acid in the control was 3×, and additional compositions were prepared whereby containing 2×, 1× and 0× gallic acid. Each cleaning composition was diluted 60:1 with deionized water. The anodic corrosion rate was measured at voltage biases ranging from 0 to 0.4V. The results are provided in Table 2.

TABLE 2
Anodic copper corrosion rate as a function
of gallic acid concentration.

| | Etch rate | Etch rate | Etch rate | Etch rate |
|---|---|---|---|---|
| Voltage Bias | (3X gal- | (2X gal- | (1X gal- | (0X gal- |
| (V vs. OCP) | lic)/Å/min | lic)/Å/min | lic)/Å/min | lic)/Å/min |
| 0 | 1.081 | 0.7524 | 0.6646 | 0.3509 |
| 0.1 | 7.612 | 5.509 | 5.675 | 3.927 |
| 0.2 | 24.07 | 17.49 | 16.02 | 13.45 |
| 0.3 | 40.10 | 30.24 | 30.48 | 28.62 |
| 0.4 | 58.23 | 44.52 | 44.29 | 45.60 |

It can be seen that decreasing the amount of gallic acid in a cleaning composition reduced the copper corrosion rate at voltage biases from 0 to 0.4V.

Advantageously, reducing the amount of gallic acid used further inhibited copper corrosion, reduced the raw material cost, enhanced the shelf life and stability of the composition, increased the pH of the cleaning composition and hence helps with the removal of BTA, and improved manufacturability.

### Example 2

A cleaning composition was prepared that comprised tetramethylammonium hydroxide, at least one amine, at least one corrosion inhibitor, at least one reducing agent, water, and 0.1 wt % surfactant. The cleaning composition was diluted 60:1 with deionized water. A second solution comprising just 0.1 wt % surfactant in water was also prepared. Foaming was judged by shaking 5 mL of each solution in 15 mL centrifuge tubes and foaming levels compared. The results are provided in Table 3.

TABLE 3
Foaming levels of 0.1 wt % surfactant
in DI water and cleaning composition.

| | Foaming in | Foaming in cleaning |
|---|---|---|
| Surfactant | DI water | composition |
| CTAB | High | High |
| Surfynol 504 | High | Low |
| DDBSA | High | Low |
| Tween 80 and Span 80 (1:1) | Low | Low |
| Zonyl FSO-100 | Low | Low |
| PEG 400 | Moderate | Low |
| Triton X-100 | High | High |
| Pluronic L61 | High | Low |
| BRIJ 35 | Moderate | Low |
| Poly(acrylic acid sodium salt) | Low | Low |
| n-dodecylphosphonic acid | Low | High |
| Plurafac RA 20 | High | Low |
| Dodecyl phosphate | High | High |

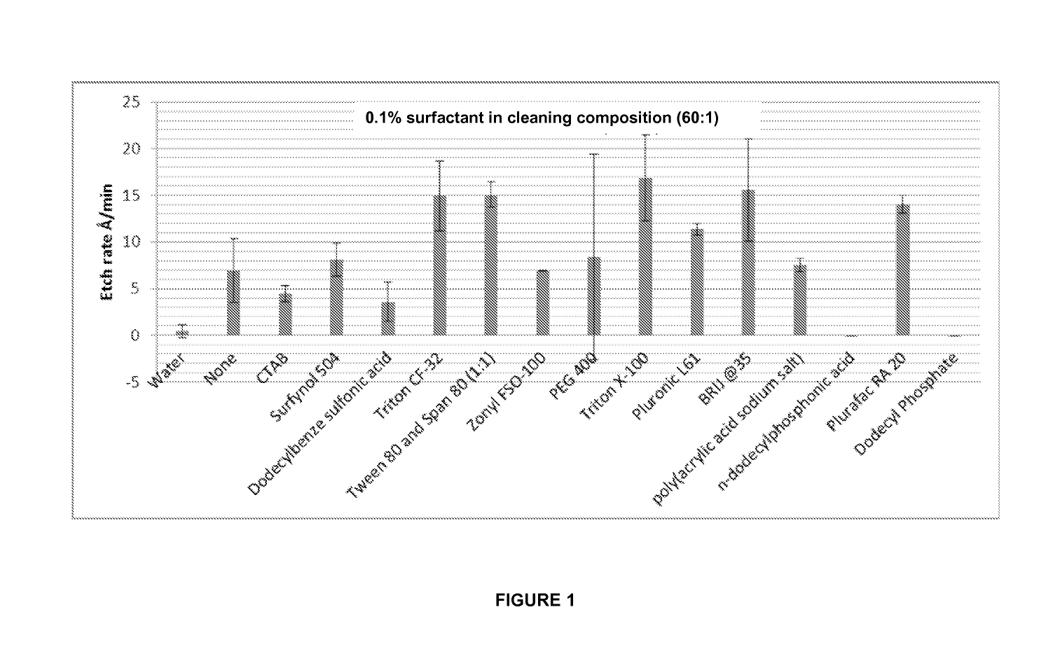

The copper etch rates of the cleaning compositions comprising the aforementioned surfactants were also determined. The etch rates are shown in FIG. 1, whereby the lowest etch rates were observed for the cleaning compositions comprising DDBSA, N-dodecylphosphonic acid, and dodecyl phosphate.

### Example 3

The barrier slurry Hitachi T915 was used to prepare a surface having slurry particles thereon. Specifically, 5% of the Hitachi T915 slurry was diluted with DI water and the pH adjusted to 5.5 using a formulation comprising 83-95.99 wt % water, 2-8 wt % TMAH, 2-8 wt % MEA, and 0.01-1 wt % adenosine (hereinafter formulation AA). To prepare the surface, the slurry is deposited for 60 sec without stirring onto a PETEOS surface and thereafter the slurry was rinsed off with water for 1 min. A variety of surfactants were added to the slurry during deposition and the average green mean intensity (AGMI) was measured to determine the extent of slurry deposition. AGMI is a measure of the light scattering from particles on the copper surface, wherein the more particles on the surface, the higher the AGMI. The method is used to estimate how many particles are on the copper surface after post-CMP cleaning. The results are shown in Table 4.

TABLE 4
Extent of slurry deposition based on surfactant used.

| Formulations | pH | AGMI | STD |
|---|---|---|---|
| 5% T915 | 5.5 | 65.7 | 2.5 |
| 5% T915 | 7 | 37.1 | 4.6 |
| 5% T915 + 0.5% Triton X-100 | 5.5 | 37.8 | 6.0 |
| 5% T915 + 0.5% DBSSA | 5.5 | 77.5 | 9.9 |
| 5% T915 + 0.5% Sokalan CP10S | 5.5 | 56.9 | 29.3 |
| 5% T915 + 0.5% PEG 400 | 5.5 | 66.5 | 12.4 |
| 5% T915 + 0.5% Tween80/Span80 | 5.5 | 127.9 | 14.3 |
| 5% T915 + 0.5% Zonyl FSO | 5.5 | 218.3 | 3.7 |
| 5% T915 + 0.5% CTAB | 5.5 | 60.2 | 11.2 |
| 5% T915 + 0.5% Pluronic F-127 | 5.5 | 57.0 | 7.2 |

It can be seen that Triton X-100, Sokalan CP10S, PEG 400 and Pluronic F-127 substantially lowered the extent of slurry deposition on the surface at pH 5.5.

### Example 5

Slurry cleaning tests were performed by dosing a copper surface for 60 sec at 0 rpm with the 5% Hitachi T915 slurry adjusted to pH 5.5 with formulation AA. The surface was then cleaned for 60 sec at 400 rpm with water or formulation AA, with and without a number of surfactants, diluted 60:1 with DI water. The average green mean intensity was measured to determine the extent of cleaning. The results are shown in Table 5.

TABLE 5
Extent of slurry cleaning

| Cleaning formulation | AGMI | STD |
|---|---|---|
| water | 204.8 | 3.5 |
| formulation AA | 91.7 | 18.5 |
| formulation AA + 0.5% Triton X-100 | 121.4 | 13.7 |
| formulation AA + 0.5% Sokalan CP10S | 81.8 | 3.2 |
| formulation AA + 0.5% PEG 400 | 75.0 | 10.6 |
| formulation AA + 0.5% Pluronic F-127 | 68.1 | 10.4 |

It can be seen that Pluronic F-127 improved the extent of cleaning of formulation AA although the other surfactants tested showed improved slurry cleaning compared to formulation AA.

### Example 6

The copper etch rate and roughness was tested for the formulations AA containing surfactants. Formulation AA, with and without surfactants, were contacted with a copper surface for time and temperature and the etch rates determined. The results are reported in Table 6 wherein it can be seen that the copper etch rates are all comparable no matter which surfactants were added.

TABLE 6
Copper etch rates with and without surfactants

| Cleaning formulation | CuER/Å min⁻¹ | STD |
|---|---|---|
| formulation AA | 3.10 | |
| formulation AA + 0.5% Triton X-100 | 3.05 | |
| formulation AA + 0.5% Sokalan CP10S | 2.85 | |
| formulation AA + 0.5% PEG 400 | 2.82 | |
| formulation AA + 0.5% Pluronic F-127 | 2.68 | |

Similar to the etch rates, there was no statistical difference when the copper roughness was measured.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art, based on the disclosure herein. The invention therefore is to be broadly construed, as encompassing all such variations, modifications and alternative embodiments within the spirit and scope of the claims hereafter set forth.

1. A cleaning composition comprising at least one solvent, at least one corrosion inhibitor, at least one amine, at least one quaternary base, and at least one surfactant, wherein the corrosion inhibitor comprises a species selected from the group consisting of: adenosine; adenine; methylated adenine; dimethylated adenine; adenosine derivatives selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof; adenosine degradation products; and combinations thereof, and wherein the at least one surfactant is selected from the group consisting of decylphosphonic acid, dodecylphosphonic acid (DDPA), tetradecylphosphonic acid, hexadecylphosphonic acid, bis(2-ethylhexyl)phosphate, octadecylphosphonic acid, perfluoroheptanoic acid, prefluorodecanoic acid, trifluoromethanesulfonic acid, phosphonoacetic acid, dodecenylsuccinic acid, dioctadecyl hydrogen phosphate, octadecyl dihydrogen phosphate, dodecylamine, dodecenylsuccinic acid monodiethanol amide, lauric acid, palmitic acid, oleic acid, juniperic acid, 12 hydroxystearic acid, dodecyl phosphate, polyoxyethylene lauryl ether, dodecenylsuccinic acid monodiethanol amide, ethylenediamine tetrakis(ethoxylate-block-propoxylate) tetrol, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether, branched, polyoxyethylene (40) nonylphenylether, branched, polyoxyethylene sorbitol hexaoleate, polyoxyethylene sorbitol tetraoleate, polyethylene glycol sorbitan monooleate, sorbitan monooleate, a combination of Tween 80 and Span 80, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazane, silicone-polyether copolymers, ethoxylated fluorosurfactants, cetyl trimethylammonium bromide (CTAB), heptadecanefluorooctane sulfonic acid, tetraethylammonium, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, Aliquat® 336 and oxyphenonium bromide, guanidine hydrochloride (C(NH₂)₃Cl), tetrabutylammonium trifluoromethanesulfonate, dimethyldioctadecylammonium chloride, dimethyldihexadecylammonium bromide, di(hydrogenated tallow)dimethylammonium chloride, phosphate polyether ester, poly(acrylic acid sodium salt), sodium polyoxyethylene lauryl ether, sodium dihexylsulfosuccinate, dicyclohexyl sulfosuccinate sodium salt, sodium 7-ethyl-2-methyl-4-undecyl sulfate, SODOSIL RM02, phosphate fluorosurfactants, ethylene oxide alkylamines, N,N-dimethyldodecylamine N-oxide, sodium cocaminpropinate, 3-(N,N-dimethylmyristylammonio)propanesulfonate, (3-(4-heptyl)phenyl-3-hydroxypropyl)dimethylammoniopropanesulfonate, cocamido propyl betaine, and combinations thereof.

2. The cleaning composition of claim 1, wherein the at least one corrosion inhibitor comprises adenosine.

3. The cleaning composition of claim 1, wherein the solvent comprises water.

4. The cleaning composition of claim 1, further comprising residue and contaminants, wherein the residue comprises post-CMP residue, post-etch residue, post-ash residue, or combinations thereof.

5. The cleaning composition of claim 1, wherein the composition is diluted in a range from about 5:1 to about 200:1.

6. The cleaning composition of claim 1, wherein the composition is substantially devoid of at least one of oxidizing agents; fluoride-containing sources; abrasive materials; an alcohol having an ether-bond in the molecule; alkylpyrrolidones; surface interaction enhancing agents; alkali and alkaline earth metal bases; sugar alcohols; corrosion inhibiting metal halides and combinations thereof; and wherein the cleaning compositions do not solidify to form a polymeric solid.

7. The cleaning composition of claim 1, wherein the amine comprises at least one species selected from the group consisting of aminoethylethanolamine, N-methylaminoethanol, aminoethoxyethanol, dimethylaminoethoxyethanol, diethanolamine, N-methyldiethanolamine, monoethanolamine, triethanolamine, 1-amino-2-propanol, 2-amino-1-butanol, isobutanolamine, triethylenediamine, other C₁-C₈ alkanolamines, tetraethylenepentamine (TEPA), 4-(2-hydroxyethyl)morpholine (HEM), N-aminoethylpiperazine (N-AEP), ethylenediaminetetraacetic acid (EDTA), 1,2-cyclohexanediamine-N,N,N′,N′-tetraacetic acid (CDTA), glycine/ascorbic acid, iminodiacetic acid (IDA), 2-(hydroxyethyl)iminodiacetic acid (HIDA), nitrilotriacetic acid, thiourea, 1,1,3,3-tetramethylurea, urea, urea derivatives, uric acid, glycine, alanine, arginine, asparagine, aspartic acid, cysteine, glutamic acid, glutamine, histidine, isoleucine, leucine, lysine, methionine, phenylalanine, proline, serine, threonine, tryptophan, tyrosine, valine, 1-methoxy-2-aminoethane, and combinations thereof; and
wherein the at least one quaternary base is selected from the group consisting of choline hydroxide and tris(2-hydroxyethyl) methylammonium hydroxide, and a compound having the formula NR¹R²R³R⁴OH, wherein R¹, R², R³ and R⁴ may be the same as or different from one another and are selected from the group consisting of hydrogen, straight-chained C₁-C₆ alkyl, branched C₁-C₆ alkyl, substituted C₆-C₁₀ aryl, and unsubstituted C₆-C₁₀ aryl.

8. The cleaning composition of claim 7, wherein the at least one quaternary base is selected from the group consisting of tetraethylammonium hydroxide (TEAH), tetramethyammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), choline hydroxide, tris(2-hydroxyethyl) methylammonium hydroxide, and combinations thereof.

9. (canceled)

10. The cleaning composition of claim 1, wherein the at least one surfactant comprises a species selected from the group consisting of dodecyl phosphonic acid, dodecyl phosphate, t-octylphenoxypolyethoxyethanol, modified polyacrylic acid in water, block copolymers based on ethylene oxide and propylene oxide, and combinations thereof.

11. The cleaning composition of claim 1, further comprising at least one additional component selected from the group consisting of at least one reducing agent, at least one complexing agent, at least one supplemental corrosion inhibitor, at least one alcohol, and NR¹R²R³R⁴OH, where R¹, R², R³ and R⁴ can be the same as or different from one another and are selected from the group consisting of H, a methyl and an ethyl group, with the proviso that at least one of R¹, R², R³ and R⁴ must be H.

12. The cleaning composition of claim 1, further comprising at least one reducing agent.

13. The cleaning composition of claim 12, wherein the at least one reducing agent comprises a species selected from the group consisting of ascorbic acid, L(+)-ascorbic acid, isoascorbic acid, ascorbic acid derivatives, gallic acid, glyoxal, and combinations thereof.

14. The cleaning composition of claim 12, wherein the at least one reducing agent comprises gallic acid and ascorbic acid.

15. A method of removing residue and contaminants from a microelectronic device having said residue and contaminants thereon, said method comprising contacting the microelectronic device with a cleaning composition for sufficient time to at least partially clean said residue and contaminants from the microelectronic device, wherein the cleaning composition includes at least one solvent, at least one corrosion inhibitor, at least one amine, at least one quaternary base, and at least one surfactant, wherein the corrosion inhibitor comprises a species selected from the group consisting of: adenosine; adenine; methylated adenine; dimethylated adenine; adenosine derivatives selected from the group consisting of 2-methoxyadenosine, N-methyladenosine, N,N-dimethyladenosine, trimethylated adenosine, trimethyl N-methyladenosine, C-4′-methyladenosine, 3-deoxyadenosine and combinations thereof; adenosine degradation products; and combinations thereof, and wherein the at least one surfactant is selected from the group consisting of decylphosphonic acid, dodecylphosphonic acid (DDPA), tetradecylphosphonic acid, hexadecylphosphonic acid, bis(2-ethylhexyl)phosphate, octadecylphosphonic acid, perfluoroheptanoic acid, prefluorodecanoic acid, trifluoromethanesulfonic acid, phosphonoacetic acid, dodecenylsuccinic acid, dioctadecyl hydrogen phosphate, octadecyl dihydrogen phosphate, dodecylamine, dodecenylsuccinic acid monodiethanol amide, lauric acid, palmitic acid, oleic acid, juniperic acid, 12 hydroxystearic acid, dodecyl phosphate, polyoxyethylene lauryl ether, dodecenylsuccinic acid monodiethanol amide, ethylenediamine tetrakis(ethoxylate-block-propoxylate) tetrol, block copolymers based on ethylene oxide and propylene oxide, polyoxypropylene sucrose ether, t-octylphenoxypolyethoxyethanol, 10-ethoxy-9,9-dimethyldecan-1-amine, Polyoxyethylene (9) nonylphenylether, branched, polyoxyethylene (40) nonylphenylether, branched, polyoxyethylene sorbitol hexaoleate, polyoxyethylene sorbitol tetraoleate, polyethylene glycol sorbitan monooleate, sorbitan monooleate, a combination of Tween 80 and Span 80, alcohol alkoxylates, alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives, siloxane modified polysilazane, silicone-polyether copolymers, ethoxylated fluorosurfactants, cetyl trimethylammonium bromide (CTAB), heptadecanefluorooctane sulfonic acid, tetraethylammonium, stearyl trimethylammonium chloride, 4-(4-diethylaminophenylazo)-1-(4-nitrobenzyl)pyridium bromide, cetylpyridinium chloride monohydrate, benzalkonium chloride, benzethonium chloride benzyldimethyldodecylammonium chloride, benzyldimethylhexadecylammonium chloride, hexadecyltrimethylammonium bromide, dimethyldioctadecylammonium chloride, dodecyltrimethylammonium chloride, hexadecyltrimethylammonium p-toluenesulfonate, didodecyldimethylammonium bromide, di(hydrogenated tallow)dimethylammonium chloride, tetraheptylammonium bromide, tetrakis(decyl)ammonium bromide, Aliquat® 336 and oxyphenonium bromide, guanidine hydrochloride (C(NH₂)₃Cl), tetrabutylammonium trifluoromethanesulfonate, dimethyldioctadecylammonium chloride, dimethyldihexadecylammonium bromide, di(hydrogenated tallow)dimethylammonium chloride, phosphate polyether ester, poly(acrylic acid sodium salt), sodium polyoxyethylene lauryl ether, sodium dihexylsulfosuccinate, dicyclohexyl sulfosuccinate sodium salt, sodium 7-ethyl-2-methyl-4-undecyl sulfate, SODOSIL RM02, phosphate fluorosurfactants, ethylene oxide alkylamines, N,N-dimethyldodecylamine N-oxide, sodium cocaminpropinate, 3-(N,N-dimethylmyristylammonio)propanesulfonate, (3-(4-heptyl)phenyl-3-hydroxypropyl)dimethylammoniopropanesulfonate, cocamido propyl betaine, and combinations thereof.

16. The method of claim 15, further comprising diluting the cleaning composition with solvent at or before a point of use, wherein said solvent comprises water.
